(19) United States
(12) Patent Application Publication
(10) Pub. No.: US 2025/0354252 A1
(43) Pub. Date: Nov. 20, 2025

(54) TITANIUM-ALUMINUM METAL ROTARY TARGET AND PREPARATION METHOD THEREFOR

(71) Applicant: Institute of New Materials Guangdong Academy of Sciences, Guangdong (CN)

(72) Inventors: Yingchun Xie, Guangdong (CN); Xin Chu, Guangdong (CN); Zeyu Hu, Guangdong (CN); Min Liu, Guangdong (CN); Chunming Deng, Guangdong (CN)

(73) Assignee: Institute of New Materials Guangdong Academy of Sciences, Guangdong (CN)

(21) Appl. No.: 19/281,113

(22) Filed: Jul. 25, 2025

Related U.S. Application Data
(63) Continuation-in-part of application No. PCT/CN2023/123487, filed on Oct. 9, 2023.

(51) Int. Cl. C23C 14/34; C23C 24/04

(52) U.S. Cl. CPC C23C 14/3414; C23C 24/04

(57) ABSTRACT

A titanium-aluminum metal rotary target and a preparation method therefor are disclosed, pertaining to the technical field of target materials. The preparation method includes following steps: preparing a pure-silver coating on a surface of a stainless-steel backing tube by a conventional cold spraying method; depositing a titanium-aluminum deposition layer on a surface of the pure-silver coating by a vacuum cold spraying method, and performing laser shock on the deposition layer using a laser shock peening process while depositing the titanium-aluminum deposition layer; and performing the above step iteratively until a total thickness of the titanium-aluminum deposition layers reaches a preset thickness.

### CROSS-REFERENCE TO RELATED APPLICATION

The present disclosure is a Continuation-in-part of the PCT international application with the filing No. PCT/CN2023/123487 filed on Oct. 9, 2023.

### TECHNICAL FIELD

The present disclosure relates to the technical field of targets, and specifically to a titanium-aluminum metal rotary target and a preparation method therefor.

### BACKGROUND ART

Titanium-aluminum targets are widely applied in preparation of reinforced thin films for drill bits and cutting tools, and can effectively prolong service lifetime of relevant components. However, it is difficult to prepare large-sized and high-density titanium-aluminum alloy targets. According to titanium-aluminum alloy phase diagram, a variety of intermetallic compounds can be formed between titanium and aluminum, resulting in processing brittleness of titanium-aluminum alloy, and high processing difficulty of titanium-aluminum alloy targets, and the fabricated titanium-aluminum alloy targets are prone to fracture under pressure-bearing working conditions due to brittleness thereof, posing potential service hazards; moreover, exothermic expansion in the alloying of elemental titanium and aluminum tends to produce bubbles and shrinkage cavities, thus failing to meet requirements for preparation of high-density titanium-aluminum targets.

In order to improve sputtering efficiency and reduce costs, sputtering targets are advancing towards large-sized development, and higher requirements are also proposed for grain size control of sputtering targets. However, the conventional processes, such as high-current heating method, hot isostatic pressing sintering method and hot-press sintering method, face challenges in the development of large-scale equipment for the preparation of large-sized tubular titanium-aluminum rotary targets.

### SUMMARY

Objectives of the present disclosure include, for example, providing a titanium-aluminum metal rotary target and a preparation method therefor.

The present disclosure provides a preparation method for a titanium-aluminum metal rotary target, including following steps:
S1: preparing a pure-silver coating on a surface of a stainless-steel backing tube by a conventional cold spraying method;
S2: depositing a titanium-aluminum deposition layer on a surface of the pure-silver coating by a vacuum cold spraying method, and performing laser shock on the deposition layer using a laser shock peening process while depositing the titanium-aluminum deposition layer; and
S3: performing S2 iteratively until a total thickness of the titanium-aluminum deposition layers reaches a preset thickness.

The present disclosure further provides a titanium-aluminum metal rotary target, prepared by the preceding preparation method.

### BRIEF DESCRIPTION OF DRAWINGS

In order to more clearly illustrate technical solutions of embodiments of the present disclosure, drawings which need to be used in the embodiments will be briefly introduced below. It should be understood that the drawings merely show some embodiments of the present disclosure, and thus should not be construed as limitation to the scope. Those ordinarily skilled in the art still could obtain other relevant drawings according to these drawings, without using any inventive efforts.

FIG. 1 is a schematic diagram of preparation of a titanium-aluminum metal rotary target provided by the present disclosure;

FIG. 2 is a principle diagram of laser shock peening in a preparation process of the titanium-aluminum metal rotary target provided by the present disclosure;

FIG. 3 is a cross-sectional view of a surface of a stainless-steel backing tube having undergone treatment of step S1 in embodiments of the present disclosure;

FIG. 4 is a microstructural diagram of a titanium-aluminum deposition layer in embodiments of the present disclosure, in which dark color is titanium, and bright color is aluminum;

FIG. 5 is a structural schematic diagram of a dumbbell-shaped titanium-aluminum metal rotary target prepared in embodiments of the present disclosure; and

FIG. 6 is a physical image of a dumbbell-shaped titanium-aluminum metal rotary target prepared in embodiments of the present disclosure.

### DETAILED DESCRIPTION OF EMBODIMENTS

In order to make objectives, technical solutions and advantages of embodiments of the present disclosure clearer, the technical solutions in the embodiments of the present disclosure will be described clearly and completely below. Embodiments, for which no concrete conditions are specified, are carried out according to conventional conditions or conditions recommended by manufactures. If manufacturers of reagents or apparatuses used are not specified, they are conventional products commercially available.

The present disclosure provides a preparation method for a titanium-aluminum metal rotary target, including following steps:
S1: preparing a pure-silver coating on a surface of a stainless-steel backing tube by a conventional cold spraying method;
S2: depositing a titanium-aluminum deposition layer on a surface of the pure-silver coating by a vacuum cold spraying method, and performing laser shock on the deposition layer using a laser shock peening process while depositing the titanium-aluminum deposition layer; and
S3: performing S2 iteratively until a total thickness of the titanium-aluminum deposition layers reaches a preset thickness.

In optional embodiments, prior to S1, the preparation method further includes: performing corrosion-controlled matrix coarsening on the surface of the stainless-steel backing tube.

In optional embodiments, matrix micro-pits corresponding to the corrosion-controlled matrix coarsening have a diameter of 5 μm and a depth of 5-8 μm.

In optional embodiments, in S1, a silver powder for preparing the pure-silver coating is a micron-sized silver powder.

In optional embodiments, the silver powder has a particle size ranging from 1 μm to 5 μm.

In optional embodiments, the silver powder has a purity of not less than 99.99%.

In optional embodiments, in S1, the conventional cold spraying includes at least one of following characteristics:
characteristic 1: a working gas being nitrogen;
characteristic 2: a spraying pressure ranging from 3 Mpa to 6 MPa;
characteristic 3: a spraying temperature ranging from 800° C. to 1000° C.; and
characteristic 4: a spraying distance being 30 mm.

In optional embodiments, prior to S2, the preparation method further includes: performing laser cleaning on an oxide film on the surface of the pure-silver coating.

In optional embodiments, in S2, a titanium source and an aluminum source for preparing the titanium-aluminum deposition layer are an elemental titanium powder and an elemental aluminum powder, respectively.

In optional embodiments, a particle size of the elemental titanium powder ranges from 0.1 μm to 30 μm, and a particle size of the elemental aluminum powder ranges from 5 μm to 45 μm.

In optional embodiments, a purity of the elemental titanium powder is no less than 99.99%, and a purity of the elemental aluminum powder is no less than 99.99%.

In optional embodiments, the elemental titanium powder accounts for 1-50% by mass of a total mass of the elemental titanium powder and the elemental aluminum powder.

In optional embodiments, in S2, the vacuum cold spraying includes at least one of following characteristics:
characteristic 1: a working gas being helium;
characteristic 2: a spraying pressure ranging from 2.5 Mpa to 3.5 MPa;
characteristic 3: a spraying temperature ranging from 400° C. to 600° C.; and
characteristic 4: a spraying distance being 30 mm.
characteristic 5: a vacuum degree during the spraying being <1 Kpa.

In optional embodiments, in S2, the laser shock peening process includes at least one of following characteristics:
characteristic 1: a laser spot diameter ranging from 4 mm to 10 mm;
characteristic 2: a laser spot overlap rate ranging from 1% to 25%; and
characteristic 3: a peak pressure ranging from 1.5 GPa to 4 GPa.

In optional embodiments, after S3, the method further includes:
S4: depositing additional 5-10 mm of titanium-aluminum deposition layers at positions of two end portions of the stainless-steel backing tube.

The present disclosure further provides a titanium-aluminum metal rotary target, prepared by the preparation method according to any one of the preceding embodiments.

In optional embodiments, the titanium-aluminum metal rotary target is dumbbell-shaped.

In optional embodiments, the pure-silver coating has a thickness of <5 μm.

In optional embodiments, the total thickness of the titanium-aluminum deposition layers ranges from 5 mm to 30 mm.

In optional embodiments, a single-layer thickness of the titanium-aluminum deposition layers is <1 mm.

The present disclosure has following beneficial effects.

The titanium-aluminum metal rotary target provided by the present disclosure is fabricated by first depositing the pure-silver coating on the surface of the backing tube using the cold spraying technique, followed by depositing the elemental titanium and aluminum powders onto the pure-silver coating by the vacuum cold spraying technique, and performing the laser shock on the titanium-aluminum deposition layer using the laser shock peening process while depositing the titanium-aluminum deposition layer. Through iterative deposition and shock peening, a large-sized titanium-aluminum metal rotary target is formed layer by layer.

The above method can effectively elevate material utilization rates while preventing oxidation and decomposition of materials, thereby retaining components of raw materials in the target. The resulting rotary target has high density, fine grains, homogeneous structure, low gas content, high interfacial adhesive strength, and remarkably enhanced target properties, without restricting the size of the target. In addition, the presence of the pure-silver coating in the target can ensure more uniform electrical conductivity and sputtering of the target.

The titanium-aluminum metal rotary target and the preparation method therefor provided by the present disclosure will be specifically illustrated below.

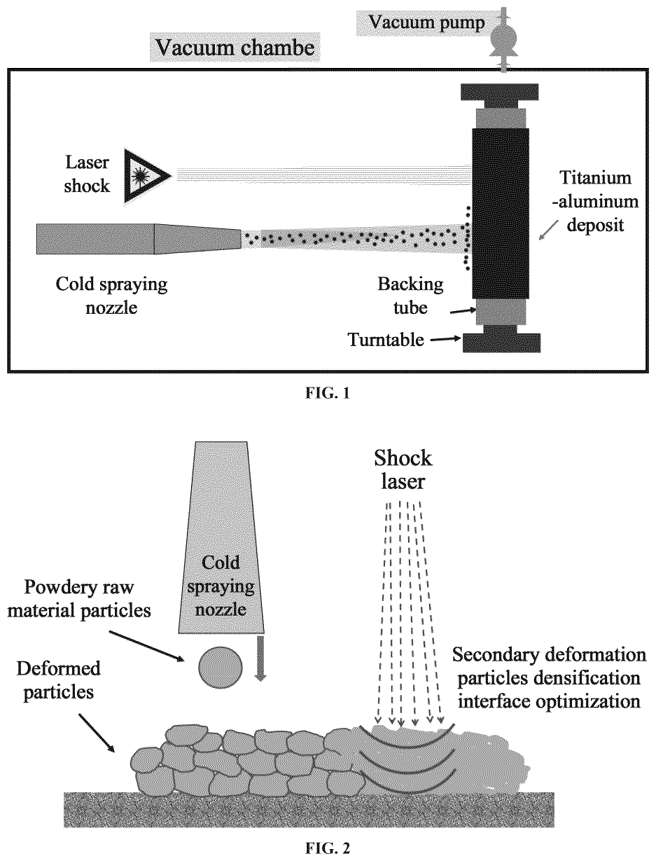

The present disclosure provides a preparation method for a titanium-aluminum metal rotary target, a preparation schematic diagram of which is as shown in FIG. 1, and a process of which includes following steps:
S1: preparing a pure-silver coating on a surface of a stainless-steel backing tube by a conventional cold spraying method;
S2: depositing a titanium-aluminum deposition layer on a surface of the pure-silver coating by a vacuum cold spraying method, and performing laser shock on the deposition layer using a laser shock peening process while depositing the titanium-aluminum deposition layer; and
S3: performing S2 iteratively until a total thickness of the titanium-aluminum deposition layers reaches a preset thickness.

In the above preparation process, the stainless-steel backing tube is placed on a turntable, and rotated at a rotational speed ranging from 200 rpm to 400 rpm.

As a reference, prior to S1, the preparation method further includes: performing corrosion-controlled matrix coarsening on the surface of the stainless-steel backing tube.

In some embodiments, the corrosion-controlled matrix coarsening can be implemented through steps of grinding, gluing, developing, etching, etc. By performing the above pre-processing on the surface of the stainless-steel backing tube, matrix micro-pits can be formed on the surface of the stainless-steel backing tube, so as to increase a contact area between the pure-silver coating and a substrate (the stainless-steel backing tube), and improve the interfacial adhesive strength.

For the above pre-processing means of grinding, gluing, developing, etching, etc., reference can be made to the related art, and details are not reiterated herein.

It should be noted that, in other embodiments, a form of the above micro-pits may not be limited to the matrix form, and may be set in any other shape and arrangement as actually required.

Exemplarily, the matrix micro-pits corresponding to the corrosion-controlled matrix coarsening may have a diameter of 5 μm and a depth of 5-8 μm (such as 5 μm, 5.5 μm, 6 μm, 6.5 μm, 7 μm, 7.5 μm or 8 μm).

In the present disclosure, in S1, a silver powder for preparing the pure-silver coating is a micron-sized silver powder.

As a reference, a particle size of the silver powder may range from 1 μm to 5 μm, for example, 1 μm, 2 μm, 3 μm, 4 μm or 5 μm. A purity of the silver powder is no less than 99.99%.

If the particle size of the silver powder is less than 1 μm, it adversely affects stable powder discharge during the spraying; and if the particle size of the silver powder is greater than 5 μm, it is challenging to prepare a thin silver coating and increases costs.

By providing the pure-silver coating between the substrate and the titanium-aluminum deposition layers, the target is enabled to have more uniform electrical conductivity and sputtering distribution.

As a reference, in S1, a working gas for the conventional cold spraying is nitrogen.

A spraying pressure ranges from 3 MPa to 6 MPa, such as 3 MPa, 3.5 MPa, 4 MPa, 4.5 MPa, 5 MPa, 5.5 MPa or 6 MPa, and may also be set at any other value within the range of 3-6 MPa.

If the spraying pressure is lower than 3 MPa, it adversely affects the preparation of high-quality deposition layers; and if the spraying pressure is greater than 6 MPa, it is prone to nozzle clogging, and gas costs are increased.

A spraying temperature may range from 800° C. to 1000° C., such as 800° C., 850° C., 900° C., 950° C. or 1000° C., and may also be set at any other value within the range of 800-1,000° C.

If the spraying temperature is lower than 800° C., it adversely affects the preparation of high-quality deposition layers; and if the spraying temperature is higher than 1000° C., it compromises stable spraying and causes nozzle clogging. A spraying distance is 30 mm.

In some preferred embodiments, prior to S2, the preparation method further includes performing laser cleaning on an oxide film on the surface of the pure-silver coating. By performing the laser cleaning with a laser cleaning agent, the oxide film on the surface of the pure-silver coating can be removed.

As a reference, in S2, a titanium source and an aluminum source for preparing the titanium-aluminum deposition layer are an elemental titanium powder and an elemental aluminum powder, respectively.

In the above, a particle size of the elemental titanium powder may range from 0.1 μm to 30 μm, such as 0.1 μm, 0.5 μm, 1 μm, 2 μm, 5 μm, 10 μm, 15 μm, 20 μm, 25 μm or 30 μm, and may also be set at any other value within the range of 0.1-30 μm.

If the particle size of the elemental titanium powder is less than 0.1 μm, it adversely affects the titanium powder deposition; and if the particle size of the elemental titanium powder is greater than 30 μm, it compromises the preparation of uniform target.

A particle size of the elemental aluminum powder may range from 5 μm to 45 μm, such as 5 μm, 10 μm, 15 μm, 20 μm, 25 μm, 30 μm, 35 μm, 40 μm or 45 μm, and may also be set at any other value within the range of 5-45 μm.

If the particle size of the elemental aluminum powder is less than 5 μm, it adversely affects uniform powder feeding; and if the particle size of the elemental aluminum powder is greater than 45 μm, it is not conducive to the preparation of high-quality coating.

Purities of the above elemental titanium powder and elemental aluminum powder are preferably no less than 99.99%.

The elemental titanium powder may account for 1-50% by mass of a total mass of the elemental titanium powder and the elemental aluminum powder, such as 1%, 2%, 5%, 10%, 15%, 20%, 25%, 30%, 35%, 40%, 45%, or 50%, and may also be set at any other value within the range of 1-50%.

Before use, the elemental titanium powder and the elemental aluminum powder are mechanically stirred and mixed uniformly at a preset ratio.

In S2, by preparing the titanium-aluminum deposition layer by the vacuum cold spraying method, oxidation phenomenon of titanium and aluminum materials during the deposition can be alleviated.

A working gas for the vacuum cold spraying is helium, and a helium recycling system helps to reduce costs.

A spraying pressure may range from 2.5 MPa to 3.5 MPa, such as 2.5 MPa, 2.8 MPa, 3 MPa, 3.2 MPa, or 3.5 MPa, and may also be set at any other value within the range of 2.5-3.5 MPa.

If the spraying pressure is lower than 2.5 MPa, it is not conducive to the preparation of high-quality deposit; and if the spraying pressure is higher than 3.5 MPa, costs are increased.

A spraying temperature may range from 400° C. to 600° C., such as 400° C., 450° C., 500° C., 550° C., or 600° C., and may also be set at any other value within the range of 400-600° C.

If the spraying temperature is lower than 400° C., it adversely affects the preparation of high-quality deposit; and if the spraying temperature is higher than 600° C., it is prone to nozzle clogging.

A degree of vacuum is controlled to be less than 1 Kpa during the spraying, and if it is greater than 1 Kpa, an unbonded defect is likely to occur at particle interfaces of the deposit. A spraying distance may be 30 mm.

In S2, a laser spot diameter of the laser shock peening process may range from 4 mm to 10 mm, such as 4 mm, 5 mm, 6 mm, 7 mm, 8 mm, 9 mm, and 10 mm, and may also be set at any other value within the range of 4-10 mm.

If the laser spot diameter is smaller than 4 mm, it cannot cover a powder spot; and if the laser spot diameter is larger than 10 mm, excessive energy introduction is likely to cause cracking of the deposit.

A laser spot overlap rate in the laser shock peening process can range from 1% to 25%, such as 1%, 2%, 5%, 8%, 10%, 15%, 20% or 25%, and may also be set at any other value within the range of 1-25%.

If the laser spot overlap rate is less than 1%, unshocked areas tend to appear; and if the laser spot overlap rate is greater than 25%, shocking efficiency is low.

A peak pressure of the laser shock peening process may range from 1.5 GPa to 4 GPa, such as 1.5 GPa, 2 GPa, 2.5 GPa, 3 GPa, 3.5 GPa, or 4 GPa, and may also be set at any other value within the range of 1.5-4 GPa.

If the peak pressure is less than 1.5 GPa, the efficiency is low, and if the peak pressure is greater than 4 GPa, low energy is too high, and it is likely to cause deposit cracking.

By performing the laser shock while depositing the titanium-aluminum deposition layer (as shown in FIG. 2), microscopic defects of the titanium-aluminum deposit can be eliminated and deposit grains can be further refined.

In the present disclosure, step S3 can be understood as performing titanium-aluminum metal layer deposition and the laser shock iteratively on the surface of the titanium-aluminum deposition layer having undergone the laser shock in step S2, so as to form the titanium-aluminum deposition layers with a preset thickness layer by layer.

Further, the present disclosure further includes step S4 after S3, that is, depositing additional 5-10 mm of titanium-aluminum deposition layers at positions of two end portions of the stainless-steel backing tube, and afterwards, a dumbbell-shaped finished target product can be formed by machining.

The above positions of the two end portions of the stainless-steel backing tube can be understood as sputtering consumable zones, with each end of the stainless-steel backing tube corresponding to these sputtering consumable zone having a length of approximately 10-30 cm. Depositing additional thicker titanium-aluminum deposition layers to the above consumable zones is conducive to significantly prolonging service lifetime of the target.

To sum up, the preparation method for a titanium-aluminum metal rotary target provided by the present disclosure can effectively improve the material utilization rates, the titanium-aluminum metal target can be formed using the elemental titanium and aluminum materials in proportion based on the cold spraying technique, the size of the target is unrestricted, and a large-scale rotary target can be prepared, for example, the size of the target can reach up to 4 m, thus greatly elevating service efficiency of the target while reducing costs of raw materials.

It should be noted that, devices involved in the conventional cold spraying process, the vacuum cold spraying process and the laser shock peening process in the present disclosure can be referenced in the related prior art, and are not limited or reiterated herein.

Correspondingly, the present disclosure further provides a titanium-aluminum metal rotary target prepared by the above preparation method.

As a reference, the titanium-aluminum metal rotary target is dumbbell-shaped.

In the titanium-aluminum metal rotary target, a thickness of the pure-silver coating can be <5 μm, such as 4.8 μm, 4.5 μm, 4 μm, 3.5 μm, 3 μm, 2.5 μm, 2 μm, 1.5 μm, 1 μm or 0.5 μm, and may also be set at other value within the range of <5 μm.

It should be noted that if the thickness of the pure-silver coating exceeds 5 μm, it is adverse to cost saving.

In the titanium-aluminum metal rotary target, the total thickness of the titanium-aluminum deposition layers may range from 5 mm to 30 mm, such as 5 mm, 8 mm, 10 mm, 15 mm, 20 mm, 25 mm or 30 mm, and may also be set at other value within the range of 5-30 mm.

A single-layer thickness of the titanium-aluminum deposition layers is <1 mm, such as 0.8 mm, 0.6 mm, 0.5 mm, 0.4 mm, 0.2 mm or 0.1 mm.

It should be noted that, by controlling the single-layer thickness of the titanium-aluminum deposition layers to be <1 mm, it facilitates performing the laser shock on the titanium-aluminum deposition layer using the laser shock peening process, thereby further refining grains of the titanium-aluminum deposit while eliminating microscopic defects of the titanium-aluminum deposit.

In addition, the titanium-aluminum metal rotary target prepared by the method provided by the present disclosure has high density, fine grains, homogeneous structure, low gas content, and high adhesive strength to the backing tube.

The resulting titanium-aluminum metal rotary target can be applied in fields of wear-resistant and friction-reducing equipment such as drills and cutting tools.

Characteristics and performances of the present disclosure are further described in detail below in conjunction with examples.

In an example, a titanium-aluminum metal rotary target was provided, and a preparation method therefor included following steps:
S0: performing grinding, gluing, developing and etching on a surface of a 304 stainless-steel backing tube having a length of 3000 mm and a diameter of 132.5 mm, so as to form matrix micro-pits having approximately a diameter of 5 μm and a depth of 6 μm on the surface of the stainless-steel backing tube (as shown in FIG. 3).
S1: depositing a pure-silver coating with a thickness of 4 μm on the surface of the stainless-steel backing tube using a cold spraying technique. In this process, a cold spraying air source was high-purity (purity 99.999%) nitrogen, a spraying pressure was 4 MPa, a temperature was 1000° C., and a spraying distance was 30 mm. A silver powder used for the spraying had a particle size ranging from 1 μm to 5 μm (with an average particle size of 4 μm), and a purity 99.99%.

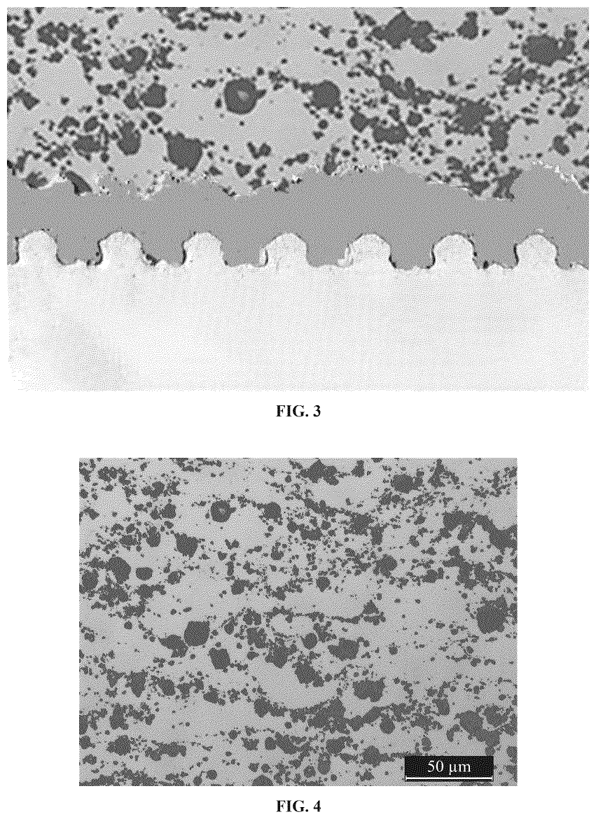

After completing the spraying, an oxide film on a surface of the pure-silver coating was removed using a laser cleaning machine.
S2: putting the backing tube coated with the pure-silver coating into a vacuum spraying chamber, depositing mixed elemental titanium and aluminum powders onto the backing tube using a vacuum cold spraying technique, with a single-layer thickness of 0.8 mm, concurrently performing laser shock densification on the titanium-aluminum deposition layer using a laser shock peening process, and performing deposition iteratively layer by layer until reaching 12 mm (see FIG. 4).

The elemental titanium powder and the elemental aluminum powder used in the above vacuum cold spraying both had a purity 99.9%, where a particle size of the elemental titanium powder ranged from 0.1 μm to 1.2 μm (with an average particle size of 0.8 μm), a particle size of the elemental titanium powder ranged from 5 μm to 45 μm (with an average particle size of 28 μm), the titanium and aluminum powders were mechanically stirred and mixed for 30 min before spraying, and the elemental titanium powder accounted for 45 wt % of a total mass of the elemental titanium powder and the elemental aluminum powder.

A working gas used for the above vacuum cold spraying was helium, a spraying pressure was 3 MPa, a spraying temperature was 500° C., a spraying distance was 30 mm, and a degree of vacuum was controlled to be <1 Kpa.

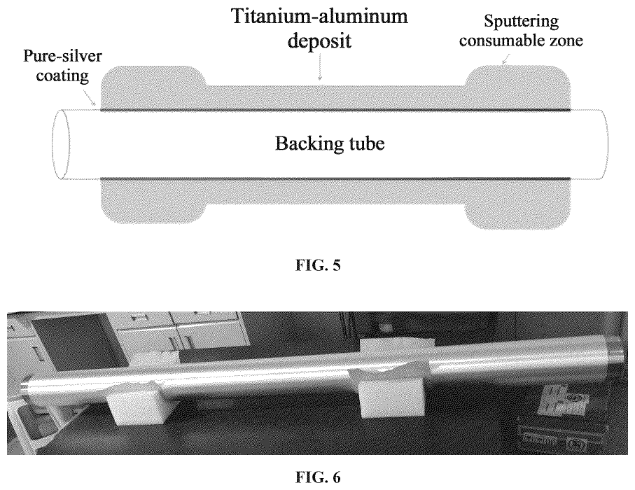

Process conditions corresponding to the above laser shock peening process were as follows: a laser spot diameter was 5 mm, a laser spot overlap rate was 5%, and a peak pressure was 2 GPa.
S4: when a target blank iteratively deposited layer by layer reached a thickness of 12 mm, further preparing 10-mm-thick titanium-aluminum composite deposition layers layer by layer in sputtering consumable zones 30 cm from two ends of the target blank, and finally forming a dumbbell-shaped finished target product by machining (as shown in FIG. 5 and FIG. 6).

In the process from S1 to S4, a turntable for placing the stainless-steel backing tube was rotated at a rotational speed of 300 rpm.

In an example, a titanium-aluminum metal rotary target was provided, and a preparation method therefor included following steps:
S0: performing grinding, gluing, developing and etching on a surface of a 304 stainless-steel backing tube having a length of 3000 mm and a diameter of 132.5 mm, so as to form matrix micro-pits having approximately a diameter of 5 μm and a depth of 8 μm on the surface of the stainless-steel backing tube.
S1: depositing a pure-silver coating with a thickness of 3 μm on the surface of the stainless-steel backing tube using a cold spraying technique. In this process, a cold spraying air source was industrial high-purity nitrogen, a spraying pressure was 6 MPa, a temperature was 1000° C., and a spraying distance was 30 mm. A silver powder used for the spraying had a particle size ranging from 1 μm to 5 μm (with an average particle size of 4 μm), and a purity 99.99%.

After completing the spraying, an oxide film on a surface of the pure-silver coating was removed using a laser cleaning machine.
S2: putting the backing tube coated with the pure-silver coating into a vacuum spraying chamber, depositing mixed elemental titanium and aluminum powders onto the backing tube using a vacuum cold spraying technique, with a single-layer thickness of 0.8 mm, concurrently performing laser shock densification on the titanium-aluminum deposition layer using a laser shock peening process, and performing deposition iteratively layer by layer until reaching 10 mm.

The elemental titanium powder and the elemental aluminum powder used in the above vacuum cold spraying both had a purity 99.9%, where a particle size of the elemental titanium powder ranged from 0.1 μm to 1.2 μm (with an average particle size of 0.8 μm), a particle size of the elemental titanium powder ranged from 5 μm to 45 μm (with an average particle size of 25 μm), the titanium and aluminum powders were mechanically stirred and mixed for 30 min before spraying, and the elemental titanium powder accounted for 40 wt % of a total mass of the elemental titanium powder and the elemental aluminum powder.

A working gas used for the above vacuum cold spraying was helium, a spraying pressure was 3 MPa, a spraying temperature was 500° C., and a spraying distance was 30 mm.

Process conditions corresponding to the above laser shock peening process were as follows: a laser spot diameter was 5 mm, a laser spot overlap rate was 5%, and a peak pressure was 2 GPa.
S4: when a target blank iteratively deposited layer by layer reached a thickness of 10 mm, further preparing 5-mm-thick titanium-aluminum composite deposition layers layer by layer in sputtering consumable zones 20 cm from two ends of the target blank, and finally forming a dumbbell-shaped finished target product by machining.

In the process from S1 to S4, a turntable for placing the stainless-steel backing tube was rotated at a rotational speed of 300 rpm.

In an example, a titanium-aluminum metal rotary target was provided, and a preparation method therefor included following steps:
S0: performing grinding, gluing, developing and etching on a surface of a 304 stainless-steel backing tube having a length of 3000 mm and a diameter of 132.5 mm, so as to form matrix micro-pits having approximately a diameter of 5 μm and a depth of 5 μm on the surface of the stainless-steel backing tube.
S1: depositing a pure-silver coating with a thickness of 1 μm on the surface of the stainless-steel backing tube using a cold spraying technique. In this process, a cold spraying air source was industrial high-purity nitrogen, a spraying pressure was 3 MPa, a temperature was 800° C., and a spraying distance was 30 mm. A silver powder used for the spraying had a particle size ranging from 1 μm to 5 μm (with an average particle size of 3 μm), and a purity 99.99%.

After completing the spraying, an oxide film on a surface of the pure-silver coating was removed using a laser cleaning machine.
S2: putting the backing tube coated with the pure-silver coating into a vacuum spraying chamber, depositing mixed elemental titanium and aluminum powders onto the backing tube using a vacuum cold spraying technique, with a single-layer thickness of 0.5 mm, concurrently performing laser shock densification on the titanium-aluminum deposition layer using a laser shock peening process, and performing deposition iteratively layer by layer until reaching 5 mm.

The elemental titanium powder and the elemental aluminum powder used in the above vacuum cold spraying both had a purity 99.9%, where a particle size of the elemental titanium powder ranged from 5 μm to 30 μm (with an average particle size of 10 μm), a particle size of the elemental titanium powder ranged from 5 μm to 45 μm (with an average particle size of 25 μm), the titanium and aluminum powders were mechanically stirred and mixed for 30 min before spraying, and the elemental titanium powder accounted for 40 wt % of a total mass of the elemental titanium powder and the elemental aluminum powder.

A working gas used for the above vacuum cold spraying was helium, a spraying pressure was 2.5 MPa, a spraying temperature was 400° C., and a spraying distance was 30 mm.

Process conditions corresponding to the above laser shock peening process were as follows: a laser spot diameter was 4 mm, a laser spot overlap rate was 1%, and a peak pressure was 1.5 GPa.
S4: when a target blank iteratively deposited layer by layer reached a thickness of 5 mm, further preparing 10-mm-thick titanium-aluminum composite deposition layers layer by layer in sputtering consumable zones 10 cm from two ends of the target blank, and finally forming a dumbbell-shaped finished target product by machining.

In the process from S1 to S4, a turntable for placing the stainless-steel backing tube was rotated at a rotational speed of 300 rpm.

In an example, a titanium-aluminum metal rotary target was provided, and a preparation method therefor included following steps:
S0: performing grinding, gluing, developing and etching on a surface of a 304 stainless-steel backing tube having a length of 3000 mm and a diameter of 132.5 mm, so as to form matrix micro-pits having approximately a diameter of 5 μm and a depth of 7 μm on the surface of the stainless-steel backing tube.
S1: depositing a pure-silver coating with a thickness of 4 μm on the surface of the stainless-steel backing tube using a cold spraying technique. In this process, a cold spraying air source was conventional industrial high-purity nitrogen, a spraying pressure was 5 MPa, a temperature was 900° C., and a spraying distance was 30 mm. A silver powder used for the spraying had a particle size ranging from 1 μm to 5 μm (with an average particle size of 2 μm), and a purity 99.99%.

After completing the spraying, an oxide film on a surface of the pure-silver coating was removed using a laser cleaning machine.
S2: putting the backing tube coated with the pure-silver coating into a vacuum spraying chamber, depositing mixed elemental titanium and aluminum powders onto the backing tube using a vacuum cold spraying technique, with a single-layer thickness of 0.1 mm, concurrently performing laser shock densification on the titanium-aluminum deposition layer using a laser shock peening process, and performing deposition iteratively layer by layer until reaching 30 mm.

The elemental titanium powder and the elemental aluminum powder used in the above vacuum cold spraying both had a purity 99.9%, where a particle size of the elemental titanium powder ranged from 10 μm to 30 μm (with an average particle size of 20 μm), a particle size of the elemental titanium powder ranged from 5 μm to 45 μm (with an average particle size of 30 μm), the titanium and aluminum powders were mechanically stirred and mixed for 30 min before spraying, and the elemental titanium powder accounted for 40 wt % of a total mass of the elemental titanium powder and the elemental aluminum powder.

A working gas used for the above vacuum cold spraying was helium, a spraying pressure was 3.5 MPa, a spraying temperature was 600° C., and a spraying distance was 30 mm.

Process conditions corresponding to the above laser shock peening process were as follows: a laser spot diameter was 10 mm, a laser spot overlap rate was 25%, and a peak pressure was 4 GPa.
S4: when a target blank iteratively deposited layer by layer reached a thickness of 30 mm, further preparing 8-mm-thick titanium-aluminum composite deposition layers layer by layer in sputtering consumable zones 30 cm from two ends of the target blank, and finally forming a dumbbell-shaped finished target product by machining.

In the process from S1 to S4, a turntable for placing the stainless-steel backing tube was rotated at a rotational speed of 300 rpm.

### Comparative Example

A comparative example was different from the examples in that: in S1, the surface of the stainless-steel backing tube was only subjected to conventional processes of grinding and sand-blasting coarsening, without forming the matrix micro-pits.

A comparative example was different from the examples in that: in S3, the mixed elemental titanium and aluminum powders were deposited on the backing tube of the target using the conventional cold spraying technique.

Spraying conditions involved in this process mainly included the following: a spraying pressure was 3 MPa, a spraying temperature was 500° C., and a spraying distance was 30 mm.

A comparative example was different from the examples in that: in S3, the laser shock peening process was not used to perform the laser shock process on a single titanium-aluminum deposition layer.

A comparative example was different from the examples in that: in S3, the single-layer thickness of the titanium-aluminum deposition layers was 2 mm.

A comparative example was different from the examples in that: the sputtering consumable zones at two ends of the target blank were not further deposited with thicker titanium-aluminum composite layers, and the finished target product was cylindrical, rather than dumbbell-shaped, that is, S4 step was omitted.

A comparative example was different from the examples in that: the surface of the backing pipe was not coated with the pure-silver coating, that is, S1 step was omitted, and S0 is directly followed by S2.

A comparative example was different from the examples in that: in S1, the depth of the matrix micro-pits was 15 μm.

A comparative example was different from the examples in that: in S1, the depth of the matrix micro-pits was 2 μm.

A comparative example was different from the examples in that: in S2, the thickness of the pure-silver coating was 10 μm.

A comparative example was different from the examples in that: in S2, the particle size of the silver powder was 0.5 μm.

A comparative example was different from the examples in that: in S2, the particle size of the silver powder was 10 μm.

A comparative example was different from the examples in that: in S2, the spraying pressure was 1 MPa.

A comparative example was different from the examples in that: in S2, the spraying pressure was 10 MPa.

A comparative example was different from the examples in that: in S2, the spraying temperature was 600° C.

A comparative example was different from the examples in that: in S2, the spraying temperature was 1200° C.

A comparative example was different from the examples in that: in S2, the spraying distance was 10 mm.

A comparative example was different from the examples in that: in S2, the spraying distance was 100 mm.

A comparative example was different from the examples in that: prior to S2, the laser cleaning was not performed on the oxide film on the surface of the pure-silver coating.

A comparative example was different from the examples in that: in S3, the particle size of the elemental titanium powder was 50 μm.

### Test Examples

Properties of the titanium-aluminum metal rotary targets obtained in the examples and comparative examples were compared, with results listed in Table 1. Herein, the adhesive strength was tested with reference to the standard in GB/T 8642-2002.

TABLE 1
Properties of Titanium-Aluminum Metal Rotary Targets

| | | | | | Overall | | |
|---|---|---|---|---|---|---|---|
| | | | | Average | target | Partial | |
| | | Oxygen | Adhesive | grain | utilization | breakdown | |
| | Porosity/% | content/ppm | strength/MPa | size/μm | rate/% | probability | Note |
| Example | 0.2 | 520 | 62 | 0.6 | 62 | Low | |
| Example | 0.1 | 560 | 58 | 0.8 | 60 | Low | |
| Example | 0.1 | 555 | 56 | 0.9 | 61 | Low | |
| Example | 0.1 | 560 | 68 | 0.7 | 60 | Low | |
| Comparative | / | / | / | / | / | / | Silver layer |
| Example | | | | | | | deposition |
| | | | | | | | failure |
| Comparative | 0.1 | 1600 | 36 | 0.8 | 52 | Low | |
| Example | | | | | | | |
| Comparative | 3.2 | 920 | 58 | 2.5 | 61 | Low | |
| Example | | | | | | | |
| Comparative | 1.3 | 760 | 62 | 1.8 | 60 | Low | |
| Example | | | | | | | |
| Comparative | 0.2 | 525 | 58 | 0.9 | 45 | Low | |
| Example | | | | | | | |
| Comparative | 0.2 | 480 | 30 | 1.1 | 56 | High | |
| Example | | | | | | | |
| Comparative | 0.2 | 560 | 12 | 0.8 | 58 | Medium | |
| Example | | | | | | | |
| Comparative | 0.1 | 580 | 31 | 0.8 | 60 | Medium | |
| Example | | | | | | | |
| Comparative | 0.1 | 480 | 61 | 0.7 | 61 | Low | High cost |
| Example | | | | | | | |
| Comparative | 0.1 | 544 | 18 | 0.9 | 58 | Medium | |
| Example | | | | | | | |
| Comparative | 0.2 | 600 | 56 | 0.8 | 58 | Low | |
| Example | | | | | | | |
| Comparative | / | / | / | / | / | / | Deposition |
| Example | | | | | | | failure |
| Comparative | / | / | / | / | / | / | Too high |
| Example | | | | | | | parameters, |
| | | | | | | | spray |
| | | | | | | | instability |
| Comparative | 0.2 | 555 | 30 | 0.9 | 61 | Medium | |
| Example | | | | | | | |
| Comparative | / | / | / | / | / | / | Too high |
| Example | | | | | | | parameters, |
| | | | | | | | nozzle |
| | | | | | | | clogging, |
| | | | | | | | spray |
| | | | | | | | instability |
| Comparative | 0.1 | 535 | 11 | 0.9 | 58 | Medium | |
| Example | | | | | | | |
| Comparative | 1.2 | 510 | 45 | 1.3 | 62 | High | |
| Example | | | | | | | |
| Comparative | 0.1 | 820 | 18 | 0.9 | 58 | Medium | |
| Example | | | | | | | |
| Comparative | / | / | / | / | / | / | Non- |
| Example | | | | | | | uniform |
| | | | | | | | elemental |
| | | | | | | | titanium |
| | | | | | | | distribution |

As can be seen from Table 1, the titanium-aluminum alloy rotary target prepared by the method provided by the present disclosure exhibits high density, fine grains, low oxygen content, high interfacial adhesive strength, high overall target utilization rate, and low partial breakdown probability.

To sum up, the titanium-aluminum metal rotary target provided by the present disclosure is fabricated by depositing the pure-silver coating with a thickness of less than 5 μm on the surface of the backing tube using the cold spraying technique, followed by depositing the elemental titanium and aluminum powders at different ratios onto the backing tube by the vacuum cold spraying technique, and performing the laser shock on the titanium-aluminum deposition layer using the laser shock peening process while depositing the titanium-aluminum deposition layer. Through iterative deposition and shock peening, the large-sized titanium-aluminum metal rotary target is formed layer by layer. The above method can effectively elevate the material utilization rates while preventing oxidation and decomposition of materials, thereby completely retaining components of raw materials in the target. The resulting rotary target has high density, fine grains, homogeneous structure, low gas content, high interfacial adhesive strength, and remarkably enhanced target properties; moreover, the size of the target is unrestricted, for example, a large-scale rotary target sized 4 meters can be prepared. In addition, the presence of the pure-silver coating in the target can ensure more uniform electrical conductivity and sputtering of the target, and the dumbbell-shaped target design can greatly improve the service efficiency of the target while reducing the costs of raw materials.

The above-mentioned are only for preferred embodiments of the present disclosure, and are not intended to limit the present disclosure, and various changes and modifications could be made to the present disclosure for those skilled in the art. Any modifications, equivalent substitutions, improvements and the like made within the spirit and principle of the present disclosure should be covered within the scope of protection of the present disclosure.

What is claimed is:

1. A preparation method for a titanium-aluminum metal rotary target, comprising following steps:
S1: preparing a pure-silver coating on a surface of a stainless-steel backing tube by a conventional cold spraying method;
S2: depositing a titanium-aluminum deposition layer on a surface of the pure-silver coating by a vacuum cold spraying method, and performing laser shock on the deposition layer using a laser shock peening process while depositing the titanium-aluminum deposition layer; and
S3: performing S2 iteratively until a total thickness of the titanium-aluminum deposition layers reaches a preset thickness.

2. The preparation method according to claim 1, prior to S1, further comprising: performing corrosion-controlled matrix coarsening on the surface of the stainless-steel backing tube.

3. The preparation method according to claim 2, wherein matrix micro-pits corresponding to the corrosion-controlled matrix coarsening have a diameter of 5 μm and a depth of 5-8 μm.

4. The preparation method according to claim 1, wherein in S1, a silver powder for preparing the pure-silver coating is a micron-sized silver powder.

5. The preparation method according to claim 4, wherein the silver powder has a particle size ranging from 1 μm to 5 μm.

6. The preparation method according to claim 4, wherein the silver powder has a purity of not less than 99.99%.

7. The preparation method according to claim 1, wherein in S1, the conventional cold spraying comprises at least one of following characteristics:
characteristic 1: a working gas being nitrogen;
characteristic 2: a spraying pressure ranging from 3 Mpa to 6 MPa;
characteristic 3: a spraying temperature ranging from 800° C. to 1000° C.; and
characteristic 4: a spraying distance being 30 mm.

8. The preparation method according to claim 1, prior to S2, further comprising: performing laser cleaning on an oxide film on the surface of the pure-silver coating.

9. The preparation method according to claim 1, wherein in S2, a titanium source and an aluminum source for preparing the titanium-aluminum deposition layer are an elemental titanium powder and an elemental aluminum powder, respectively.

10. The preparation method according to claim 9, wherein a particle size of the elemental titanium powder ranges from 0.1 μm to 30 μm, and a particle size of the elemental aluminum powder ranges from 5 μm to 45 μm.

11. The preparation method according to claim 9, wherein a purity of the elemental titanium powder is no less than 99.99%, and a purity of the elemental aluminum powder is no less than 99.99%.

12. The preparation method according to claim 9, wherein the elemental titanium powder accounts for 1-50% by mass of a total mass of the elemental titanium powder and the elemental aluminum powder.

13. The preparation method according to claim 1, wherein in S2, the vacuum cold spraying comprises at least one of following characteristics:
characteristic 1: a working gas being helium;
characteristic 2: a spraying pressure ranging from 2.5 Mpa to 3.5 MPa;
characteristic 3: a spraying temperature ranging from 400° C. to 600° C.; and
characteristic 4: a spraying distance being 30 mm.
characteristic 5: a vacuum degree during the spraying being <1 Kpa.

14. The preparation method according to claim 1, wherein in S2, the laser shock peening process comprises at least one of following characteristics:
characteristic 1: a laser spot diameter ranging from 4 mm to 10 mm;
characteristic 2: a laser spot overlap rate ranging from 1% to 25%; and
characteristic 3: a peak pressure ranging from 1.5 GPa to 4 GPa.

15. The preparation method according to claim 1, after S3, further comprising:
S4: depositing additional 5-10 mm of titanium-aluminum deposition layers at positions of two end portions of the stainless-steel backing tube.

16. A titanium-aluminum metal rotary target, prepared by the preparation method according to claim 1.

17. The titanium-aluminum metal rotary target according to claim 16, wherein the titanium-aluminum metal rotary target is dumbbell-shaped.

18. The titanium-aluminum metal rotary target according to claim 16, wherein the pure-silver coating has a thickness of <5 μm.

19. The titanium-aluminum metal rotary target according to claim 16, wherein the total thickness of the titanium-aluminum deposition layers ranges from 5 mm to 30 mm.

20. The titanium-aluminum metal rotary target according to claim 16, wherein a single-layer thickness of the titanium-aluminum deposition layers is <1 mm.
